(19) United States
(12) Patent Application Publication
(10) Pub. No.: US 2011/0232744 A1
(43) Pub. Date: Sep. 29, 2011

(54) PHOTO ELECTRIC TRANSDUCER

(76) Inventors: Jens William Larsen, Dronninglund (DK); Hans-Erik Kiil, Aabenraa (DK)

(21) Appl. No.: 13/062,040

(22) PCT Filed: Sep. 3, 2009
(86) PCT No.: PCT/DK2009/050223

§ 371 Date: May 12, 2011

(30) Foreign Application Priority Data
Sep. 5, 2008 (EP) 08163782.9

(51) Int. Cl. H01L 31/0236; H01L 33/36

(52) U.S. Cl. 136/256; 257/99; 257/E33.066

(57) ABSTRACT

A photoelectric transducer comprising in order: a substrate (1, 5), a rear side electrode (2, A), a photoelectric active (photovoltaic) layer (3), and a front side electrode (4, B). The substrate (1, 5) is constituted by a flexible, elastic web or foil, that on a front side of the substrate has a three-dimensional surface pattern of raised and depressed surface portions formed therein. The photoelectric active (photovoltaic) layer (3) is deposited onto the three-dimensional surface pattern. The front side electrode (4, B) and rear side electrode (2, A) are electrically conductive layers, which comprise electrically conductive materials, or which are electrically conductive coatings. The elasticity and flexibility are important features making possible to durably mount the solar cell of the invention on complex surfaces comprising inwardly bending (concave) as well as outwardly bending (convex) surface parts.

### BACKGROUND OF THE INVENTION

1. Field of the Invention

The present invention relates to a photoelectric transducer.

A “transducer” shall in connection with the present invention be understood as a generic device for transforming one energy form to another energy form, which by way of example solar light to electricity, or electricity to electromagnetic radiation, such as light.

Known solar cells usually have a relative small area on a relative stiff substrate, which thus may be an additional reason for the limitation of the practical area of use of solar cells.

2. Description of the Prior Art

WO 2008/010205 A2 discloses a thin-film photovoltaic conversion device, formed on a substrate, preferably made of a flexible plastic, having first and second conductive layers as electrodes, n-type and p-type layers, a graded (varizone) band gap layer including pure silicon and silicon in chemical compositions selected from a group, consisting of SiₓGe₁₋ₓ, SiₓC_{y}, SiₓN_{y} and SiₓO_{y}N₂. All of these chemical compositions simultaneously comprise in graded band gap layer and smoothly changing from one to the other. The photovoltaic device additionally comprises reflective layer, an anti-reflective layer and a protective laminating layer.

### SUMMARY OF THE INVENTION

The invention is a transducer, which is provided in an elastic or compliant manner, such that the field of application of the transducer in practice may be considerably increased, and such that it is possible to attach the transducer to various surfaces and possibly varying shapes.

The substrate of the transducer according to the invention is constituted by a flexible, elastic web or foil, with a front side of the substrate including a three-dimensional surface pattern of raised and depressed surface portions formed therein. The photoelectric active (photovoltaic) layer is deposited onto the three-dimensional surface pattern with the front side electrode and rear side electrode being constituted by electrical conductive layers comprising electrical conductive materials, or which is provided with electrical conductive coatings.

In a simple manner an improved transducer is achieved which is flexible and elastic, and which in addition provides the flexible transducer with very important elastic or compliant properties and increase the general area of use of the transducer significantly.

Furthermore, the elastic or compliant properties of the transducer make it possible to attach the transducer to surfaces of various shapes, by way of example curved surfaces including even double curved surfaces.

It is also possible to attach the transducer to a surface having a shape which varies over time, by way of example due to environmental factors, such as changes in temperature, changes in moisture level, vibrations, shock, etc. Since the compliant properties of the transducer allows it to follow such changes in shape of the surface having the transducer attached thereto, damage carried by shape changes is prevented to the transducer, by way of example in the form of cracks, fractures or tension. Therefore, the lifetime of the solar cell may thereby be prolonged.

The substrate may be constituted by a polymer elastomer web or foil. Elastomer materials are known to have compliant properties.

Preferably, the transducer according to the invention includes a substrate constituted by a silicone web or foil. The transducer according to the invention has a decreased weight as compared to transducers having a substrate made from a glass material or a metal, such as steel.

Furthermore, the lifetime of the transducer is increased, because silicone is stable over time with respect to solar light since the compliancy of the silicone web or foil is adapted to prevent transfer of mechanical tensions to the active layer in case of temperature variations or other mechanical effects. Finally, the manufacturing costs can be minimized because all process steps can be performed in an inline roll-to-roll process, and because the electrical connections between pluralities of cells in a solar panel can be deposited directly onto the substrate.

As an alternative, the substrate may be constituted by a polyurethane web or foil. Polyurethane is a relative cheap material, and polyurethane is furthermore easy to work with, because it relatively quickly achieves a stable, durable state.

The transducer may further comprise a top protection layer, arranged to protect the active parts of the transducer from wear and tear, as well as impact caused by the weather. Appropriately, the transducer according to the invention is furthermore provided such that the possible protection layer is a transparent, elastic or compliant silicone web or foil.

A transducer according to the invention in the form of a flexible, elastic solar cell having a top protection layer, which includes by a transparent, flexible silicone web or foil is appropriate for mounting onto a transparent surface such as a window pane.

In order to further improve the elasticity and the efficiency of the transducer according to the invention, the front side of the substrate is provided with a surface pattern of raised and depressed surface portions onto which the photoelectric active (photovoltaic) layer is deposited. It is an advantage that the raised and depressed surface portions are formed directly as a surface pattern on the substrate, rather than being formed by pre-straining or compressing the substrate or the transducer, because it is easier to control the direction of compliance, and because it is possible to design and control the pattern, including the size and shape of the raised and depressed surface pattern, in a very accurate manner. Thereby the properties of the transducer can be controlled and designed as desired.

The photoelectric active (photovoltaic) layer may be in the form of a silicon compound which by way of example comprises amorphous or crystalline silicon.

More specifically, the transducer according to the invention may be provided the surface pattern comprising waves forming troughs and crests extending essentially in one common direction. Each wave defines a height which is a shortest distance between a crest and neighboring troughs. According to this embodiment, the surface pattern provides compliance of the substrate along one direction, while the substrate is substantially stiff along a direction substantially perpendicular to the compliant direction. Thus, the waves define an anisotropic characteristic facilitating movement in a direction which is perpendicular to the common direction. According to this embodiment, the crests and troughs resemble standing waves with essentially parallel wave fronts.

However, the waves are not necessarily sinusoidal, but could have any suitable shape as long as crests and troughs are defined. According to this embodiment, a crest (or a trough) defines substantially linear contour-lines, that is in general, lines along a portion of the corrugation with equal height relative to the substrate. This at least substantially linear line will be at least substantially parallel to similar contour lines formed by other crest and troughs, and the directions of the at least substantially linear lines define the common direction. The common direction defined in this manner has the consequence that anisotropy occurs, and that movement of the transducer in a direction perpendicular to the common direction is facilitated, that is the transducer, or at least a photoelectric active layer arranged on the corrugated surface is compliant in a direction perpendicular to the common direction. As a consequence, the transducer can be attached to a curved surface without introducing cracks or creases in the transducer, because the transducer is capable of stretching and/or compressing along the compliant direction to follow the curves of the surface.

The photoelectric active (photovoltaic) layer may be provided with a photoelectric active coating in the form of a silicon compound, by way of example comprising amorphous or crystalline silicon.

As an alternative, the surface pattern may comprise waves forming troughs and crests extending essentially in at least two directions along the surface of the substrate. According to this embodiment, the substrate is compliant, and thereby stretchable, along at least two directions. As a consequence, it is possible to attach the transducer to a double curved surface without introducing cracks or creases in the transducer, since the transducer is capable of stretching along the two compliant directions. Thereby it is possible to attach the transducer to a large variety of different kinds of surfaces, such as cars or other vehicles, clothing, sports equipment, facades of buildings, etc. It is even possible to attach the transducer to a surface which changes shape over time.

According to one embodiment, the surface pattern may comprise waves forming troughs and crests, with the troughs and crests defining wave fronts extending essentially in at least two directions along the surface of the substrate. Thus, according to this embodiment, the surface pattern comprises crests similar to hilltops with the hilltops being arranged on the surface so that substantially parallel lines can be drawn between groups of neighboring hilltops with the parallel lines defining wave fronts. The wave fronts are defined along at least two directions along the surface of the substrate, for example, along two directions arranged substantially perpendicular to each other, or along three directions arranged with a mutual angle of approximately 120°. Accordingly, similarly to what is described above, the substrate is in this case compliant along at least two directions, which are the directions defined by the extension of the wave fronts so that the substrate carrying the transducer can thereby be attached to double curved surfaces as described above.

The surface pattern may define a plurality of funnels so that each funnel defines interior wall parts arranged relative to each other so that light incident on an interior wall part of a funnel is reflected onto another interior wall part of the funnel. According to this embodiment, the surface pattern is designed so that it provides so-called “light-trapping”. Thereby it is ensured that light with various angles of incidence reaches the photoelectric active (photovoltaic) layer. Furthermore, it is ensured that the part of the incident light which is reflected from an interior wall part reaches another interior wall part, so that the reflected light also reaches the photoelectric active (photovoltaic) layer for possibly multiple times. Thereby the efficiency of the transducer is significantly increased.

The interior wall parts may advantageously be arranged in such a manner that they define an angle therebetween with the angle being smaller than 60°, such as smaller than 50° or smaller than 40°.

The funnels may advantageously be provided as microstructures, as nanostructures or as a combination of microstructures and nanostructures.

In general the transducer according to the invention is provided such that the photoelectric active layer has a shape which is formed by the surface pattern of the substrate. To enable elongation of the transducer in one or more directions, to provide compliance, the photoelectric active layer is preferably a corrugated shape which renders the area of the photoelectric active layer larger than the area occupied by the transducer in a relaxed state.

The corrugated shape of the photoelectric active layer thereby facilitates the transducer being stretched and/or compressed to follow the shape of a surface onto which the transducer is mounted, without having to stretch the photoelectric active layer by merely evening out the corrugated shape of the photoelectric active layer. According to this embodiment, the corrugated shape of the photoelectric active layer is a replica of the surface pattern of the substrate.

The transducer may advantageously be a solar cell. In this case the transducer according to the invention may furthermore be a solar cell comprising a photovoltaic part and a thermoelectric part disposed adjacent to each other.

Preferably, in this embodiment the transducers may have the photovoltaic part disposed in a front position and the thermoelectric part disposed in a rear position. It is common that part of the energy received by a solar cell from incoming sun light is absorbed in the form of heat in the solar cell, rather than being transformed into electricity. Apart from the fact that this heat may be detrimental to the solar cell, it also represents an energy loss in the system. By disposing a photovoltaic part in a front position and a thermoelectric part in a rear position, the photovoltaic part initially transforms a part of the incident light into electricity. Subsequently, the thermoelectric part transforms at least part of the absorbed heat in the solar cell into electricity. Therefore, the total yield of the solar cell is increased.

In another embodiment of the invention, the transducer is a light emitting device. In this embodiment a voltage is applied to the electrical conductive terminals on the rear side and the front side, which will reverse the function of the transducer to emit photons as light.

Given the three-dimensional surface pattern of the raised and depressed surface portions, the surface serves as a light emitter from which the photons will escape the “light-trap” in an opposite direction compared to the capture of light when the transducer is working as a solar cell.

Having a randomly formed surface, the light will escape in a diffuse way suitable for creating a subtle lighting element ideal for providing a luminescent layer. If given an orderly formed surface, the light will escape in an orderly predetermined manner.

It should be noted that the present invention covers transducers operating purely as solar cells, transducers operating purely as light emitting devices and transducers which are capable of operating as a solar cell and as a light emitting device.

### BRIEF DESCRIPTION OF THE DRAWINGS

The invention is described in more detail with reference to the drawing, in which:

FIG. 1 shows a plane sectional view of an embodiment of a solar cell according to the invention formed on a silicone web or foil;

FIG. 2 shows a perspective view of the solar cell of FIG. 1 as seen from above;

FIG. 3 shows a plane view, partly in section, of another embodiment of a solar cell according to the invention formed on a silicone foil or web and with a protecting silicone foil on the front side;

FIG. 4 shows a perspective view of the solar cell of FIG. 3 as seen from above;

FIG. 5 shows at the top a plane view of a rolled up transducer to the left-hand side ; to the right-hand side an enlarged view of the upper surface of the transducer; and a lower sectional view showing the different layers of the transducer;

FIG. 6 shows a perspective view of an embodiment of the corrugation of the front surface of a substrate of a transducer according to the invention;

FIG. 7 shows a plane sectional view of an embodiment of a transducer in the form of a combined solar cell and thermoelectric cell according to the invention;

FIG. 8 shows a plane sectional view illustrating “light trapping” of light beams between the waves of the corrugated surface of the substrate of a transducer in the form of a solar cell according to the invention;

FIG. 9 shows a perspective view of another embodiment of the corrugation of the front surface of a substrate of a solar cell according to the invention;

FIG. 10 shows a perspective view illustrating a possible surface pattern of the front surface of a substrate for a solar cell according to the invention; and

FIG. 11 shows a 3D view of a part of an embodiment of solar cell according to the invention—illustrating the flexibility as well as the elasticity of the silicone web or foil substrate.

### DETAILED DESCRIPTION OF THE INVENTION

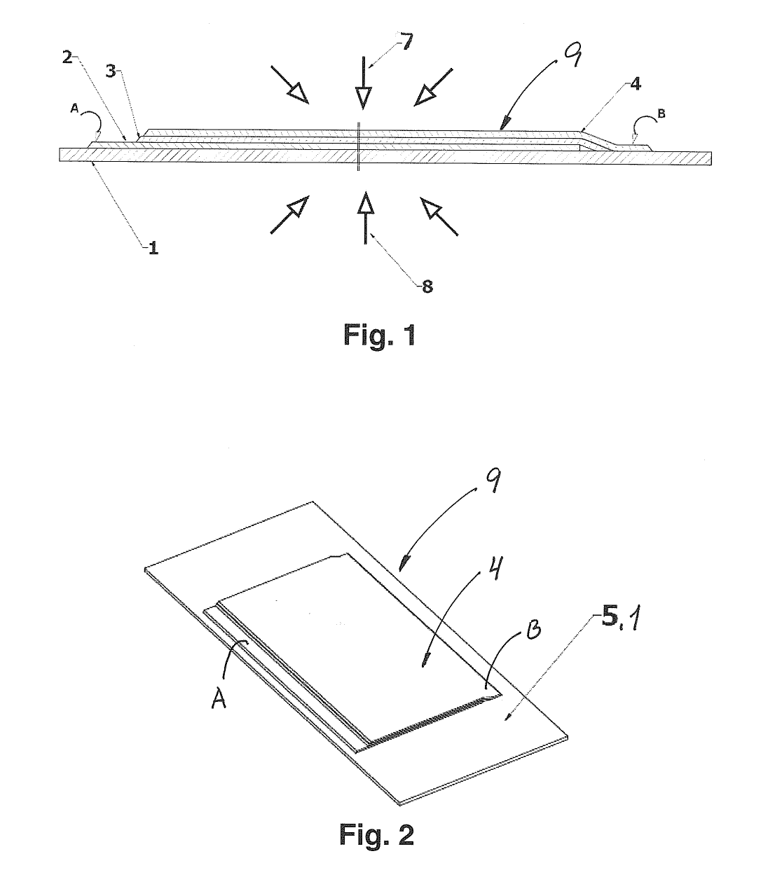

The transducer 9 shown in FIGS. 1 and 2 formed on a substrate or carrying material in the form of a silicone web or foil 1, 5. On top of the silicone web or foil 1, 5 is deposited a rear side electrode 2, A as an electrically conductive layer in a layer of silver (Ag) deposited by DC-sputtering in an argon (Ar) atmosphere.

By RF-/DC-sputtering one or more group of layers are then deposited each having a n-Si layer, a i-Si layer and a p-Si layer constituting the photoelectric active layer 3 of the surface pattern of the front side of the substrate in an atmosphere of argon/hydrogen (Ar/H₂). The photovoltaic layer 3 may very often comprise up to three or more groups of n-Si, i-Si and p-Si layers.

Afterwards a front side electrode 4, B is deposited by RF sputtering either as a layer of indium tin oxide (ITO) or a layer of zinc oxide (ZnO₂) in both cases in an argon/oxygen (Ar/O₂) atmosphere. The in-coming light to the transducer 9, is indicated by arrows 7, while arrows 8 at the opposite side of the solar cells 9, indicate a possible view out through the solar cell. If the silicone substrate of the transducer 9 is transparent, then also the whole transducer 9 may be transparent.

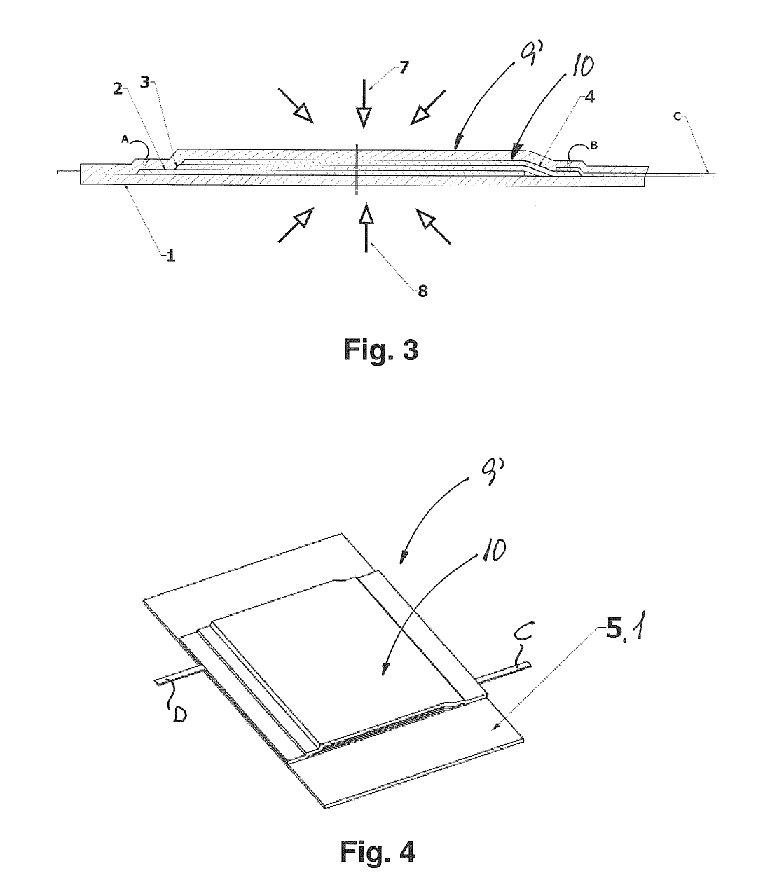

The transducer 9′ shown in FIGS. 3 and 4 includes most of the above-described items of the solar cell 9 wherein in FIGS. 1 and 2 the same reference numerals are used for identical items. However, the transducer 9′ shown in FIGS. 3 and 4 comprises a further upper protective layer 10 in the form of a possible transparent silicone web or foil 10. Additionally, the transducer 9′ shown in FIGS. 3 and 4 comprises an electrically conductive terminal D connected to the rear side electrode 2, A and an electric conductive terminal C connected to the front side electrode 4, B.

The transducers 9, 9′may furthermore comprise an upper anti-reflective layer (ARC), which is not illustrated, that is deposited to the upper surface of the transducers 9, 9′ in an argon (Ar) atmosphere.

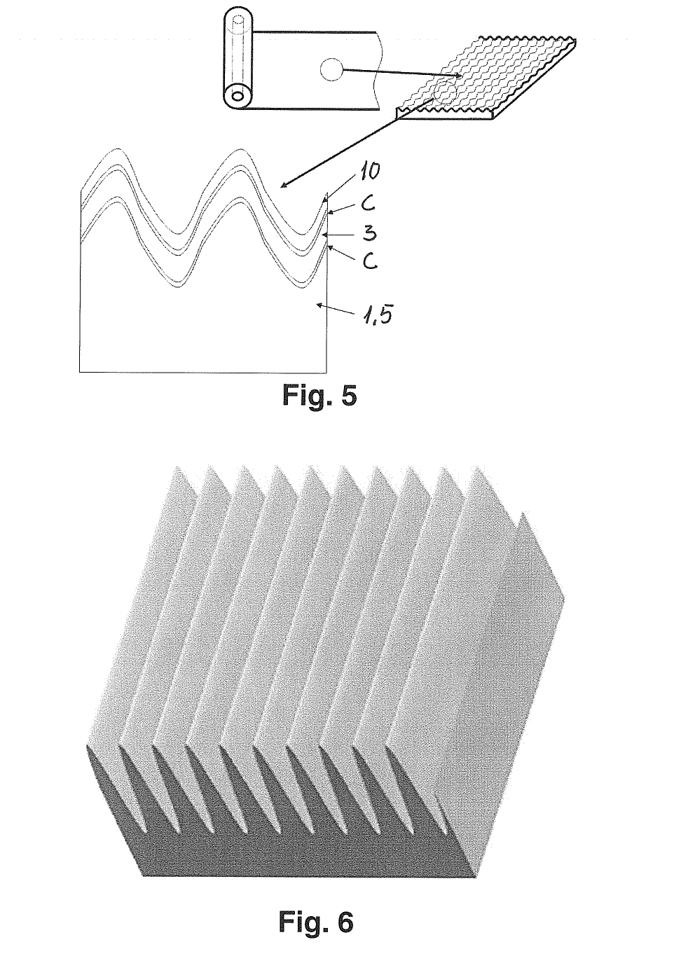

In three steps, FIG. 5 shows a plane view of a rolled up transducer according to the invention in the left-hand side in the upper part of FIG. 5; the right-hand side shows an enlarged perspective view of the corrugated upper surface of the substrate of the transducer and a lower further enlarged sectional view shows the different layers of the transducer 9′, which are an upper protective layer 10, a top electrode C, more electricity generating layers 3 and a coated silicone web or foil 1, 5 with 3D surface structure.

The upper surface of the substrate shown in FIG. 5 is corrugated in two directions along the surface. Thus, it can be seen from FIG. 5 that it is possible to draw parallel lines between neighboring crests or hilltops along a longitudinal direction of the substrate as well as along a transversal direction of the substrate. Accordingly, the solar cell is compliant in two directions, and it can thereby be stretched and/or compressed to fit surfaces of various shapes, such as double curved surfaces, as described above.

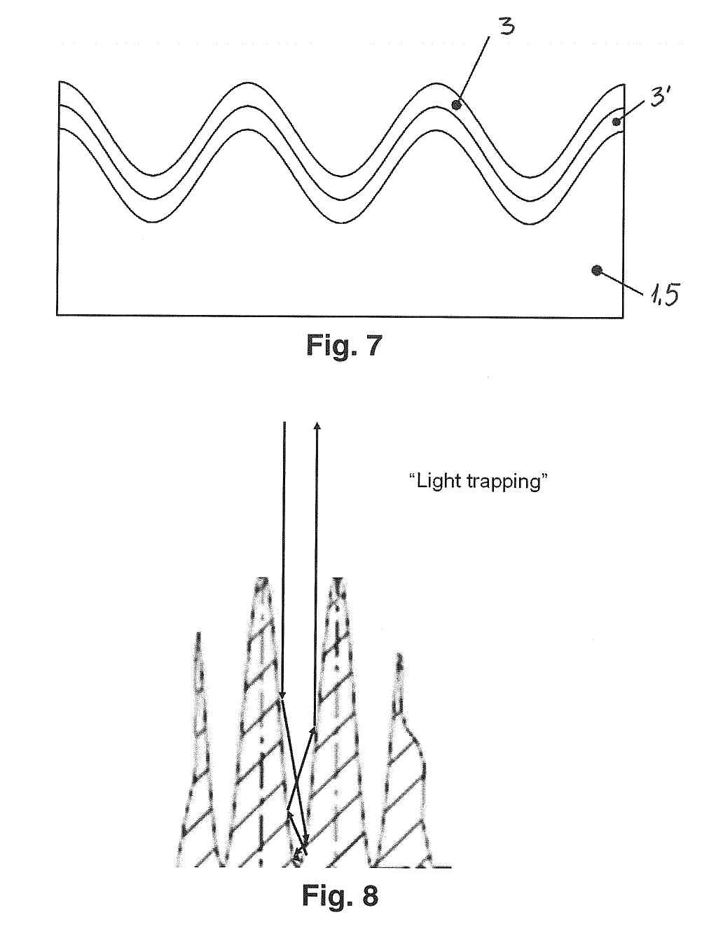

FIGS. 6 and 7 show, in a highly enlarged scale, an embodiment of a transducer substrate according to the invention in the form of a silicone web having 3D surface structure with uniform straight waves. The transducer substrate shown in FIGS. 6 and 7 is provided with a surface pattern of raised and depressed surface portions in the form of waves having troughs and crests extending essentially in one common direction. Thus, the transducer substrate of FIGS. 6 and 7 is compliant along a direction which is substantially perpendicular to the direction defined by the wave fronts, that is along a longitudinal direction of the substrate. The transducer substrate is relatively stiff along the direction defined by the wave fronts. Thereby the transducer can be stretched in the compliant direction, but not in the transversal direction.

FIG. 8 shows, in a highly enlarged scale, the situation called “light trapping” where an incoming light beam is reflected several times on the corrugated (waved) surface of a substrate of a solar cell and finally is possibly residual light thrown back from the solar cell. Such “light trapping” in the surface of a transducer may cause an improvement of the efficiency of the transducer.

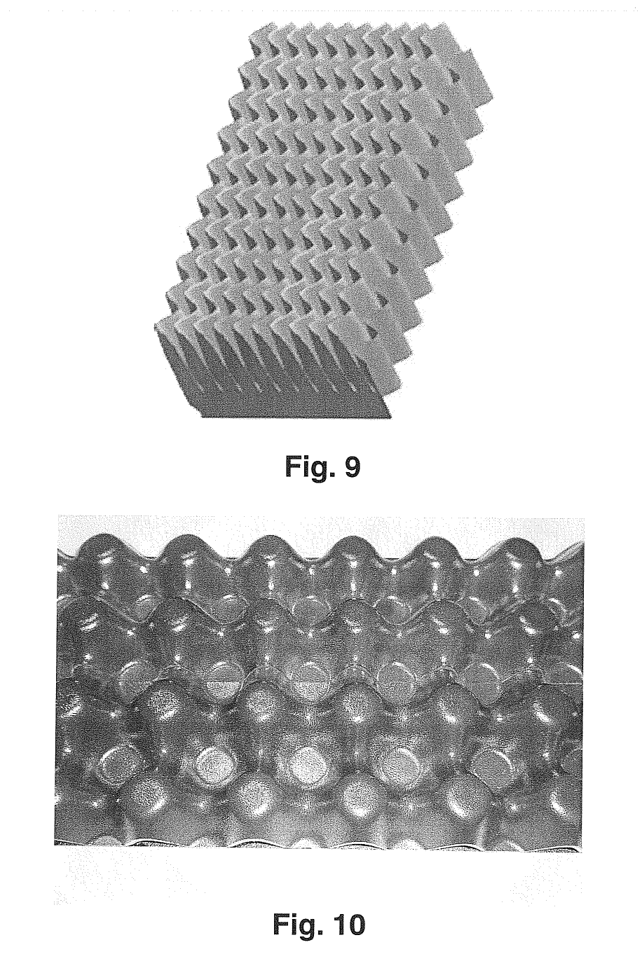

FIG. 9 shows, in a highly enlarged scale, a further embodiment of a transducer substrate according to the invention in the form of a silicone web having a 3D surface structure with uniform waves with corrugations in more directions. Hereby the active surface of the solar cell may be significantly enlarged in order to improve the efficiency of the transducer.

Furthermore, the transducer substrate is compliant in a longitudinal direction as well as in a transversal direction. Therefore, the transducer is stretchable in both of these directions, and it is therefore possible to mount the transducer on a large variety of different surfaces, such as double curved surfaces, which by way of example, may be concave or convex surfaces, without risking introduction of cracks or creases in the substrate.

Furthermore, since the photoelectric active layer is coated onto the substrate to adopt the shape of the surface pattern, the photoelectric active layer simply moves along with the surface of the substrate when it is stretched and/or compressed, and thereby no stress is introduced in the photoelectric active layer.

FIG. 10, shows in a highly enlarged scale, a still further embodiment of the surface of a transducer substrate according to the invention in the form of a silicone web having a great number of blunt peaks and valleys (similar to an egg tray) in order to enlarge the surface area and thereby improve the efficiency of the transducer. Furthermore this embodiment of the surface of the transducer may cause an improved efficiency by the fact that incoming solar light from different directions may hit the inclined sides of the blunt peaks as well as the bottom surfaces of the valleys. Furthermore, in the surface pattern shown in FIG. 10, it is possible to draw parallel lines between neighboring peaks along at least three different directions along the surface of the substrate. Accordingly, the substrate shown in FIG. 10 is compliant in at least three directions.

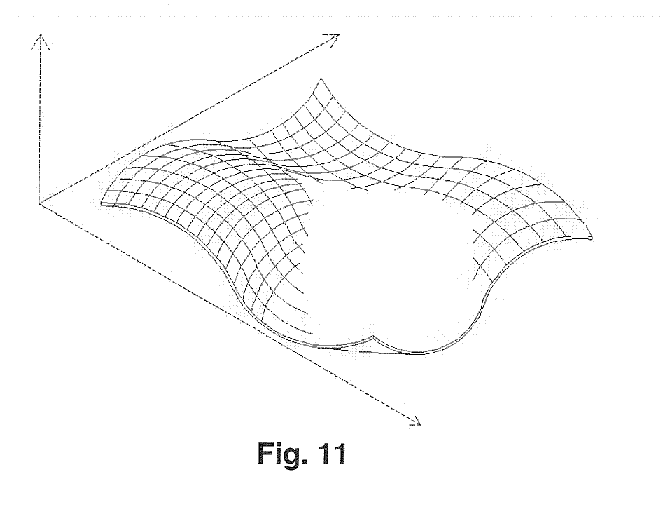

FIG. 11 shows a perspective, 3D view of a part of an embodiment of a transducer having a silicone substrate according to the invention which illustrates the flexibility as well as the elasticity of the silicone substrate of the transducer. The elasticity together with the flexibility are very important features in order to make possible durably mounting the transducer on complex surfaces comprising inwards bending (concave) as well as outwards bending (convex) surface parts.

As described above, the silicone substrate in itself possesses elastic properties allowing the substrate to be stretched to some extent. However, providing the surface of the silicone substrate with a surface pattern defining troughs and crests along one, two or more directions significantly enhances the elastic properties of the substrate. It should be noted that the elasticity of the transducer renders the transducer robust with respect to changes in the dimensions and/or shape of a surface having the transducer attached thereto, since the elasticity of the transducer allows it to change its shape to follow the changes in the mounting surface. This prolongs the expected lifetime of the transducer and allows it to be attached to an even larger variety of different kinds of surfaces. Changes in the dimensions and/or shape of a surface having the transducer attached thereto may by way of example be caused by environmental influences, such as changes in temperature, changes in moisture level, vibrations, shocks, etc.

The rear side electrode and the top side electrode of the transducer according to the invention of course have to be connected with an electrical controlling circuit or other electrical devices in a proper manner by way of example by means of contact portions or connectors as describes in WO 2008/052559 A2 on page 50, line 21, to page 53, line 6, and in FIGS. 23-36.

In the preferred method of the production of the transducer according to the invention, a silicone substrate is a first layer, with the front side facing upwards, by being supported on a top course of an endless conveyor or a similar transportation unit in successive order through the following treatment stations:
in a first treatment station, providing the surface pattern of the front side of the substrate with a plasma treating in an argon (Ar) atmosphere;
in a second treatment station, applying by DC-sputtering a rear side electrode in the form of a layer of silver (Ag) in an argon (Ar) atmosphere;
in a third treatment station, applying by RF-/DC-sputtering one or more group of layers each of a n-Si layer, a i-Si layer and a p-Si layer to the surface pattern of the front side of the substrate in an atmosphere of argon/hydrogen (Ar/H₂);
in a fourth treatment station, applying by RF-sputtering a front side electrode either in the form of a layer of indium tin oxide (ITO) or in the form of a layer of zinc oxide (ZnO₂) which in both cases is in an argon/oxygen (Ar/O₂) atmosphere'
in a possible fifth treatment station, applying an anti-reflective (ARC) layer in an argon (Ar) atmosphere; and
in a final treatment station, at the end of the endless belt conveyor, rolling up the finished transducer.

By the surface treatment in the first treatment station, microscopic quartz crystals (SiO₂) or other quartz grains/structures are formed on the front side surface of the silicone substrate, by way of example, by reconstructing or transforming residual compounds and/or depositing of supplementary compounds. Thereby the adherence of front side surface is significantly improved for the subsequent application of further layers onto the front surface of the front side surface of the silicone substrate.

In the third treatment station, RF-/DC-sputtering in an argon atmosphere typically forms a number of groups of at least three layers (p-Si layer, i-Si layer and n-Si layer) constituting the active electricity generating layer of the transducer. The groups of layers are positioned on or between one or more layers of a silicone based web/foil or other geometric shape.

The three layers (or more) of the active layer of the solar cell are respectively a top electrode, which is transparent and electrically conductive (TCO—Transparent Conductive Oxide), the photo active (photovoltaic) layer, and the electrically conductive rear side electrode, which may be transparent or partly transparent or not transparent at all.

The active layer of the transducer is coated on or joined with a substrate of a silicone based polymer or elastomer. The polymers or elastomer may comprise a silicon compound.

The silicone substrate of the solar cell may be (but not necessarily) provided with fibers or other reinforcing elements, which increases the tensile strength and thereby the lifetime and makes the mounting easier.

The silicone substrate of the solar cell may be (but not necessarily) laminated or in another way joined together with another flexible or not flexible substrate in order to increase the tensile strength. Such increased tensile strength may be advantageous during the production, during the mounting, as well as during the use of the solar cell.

The primary purposes of the present invention can be listed as follows:
to provide a solar cell on a silicone containing polymer (elastomer) substrate, web or foil;
to form a photovoltaic cell module on a silicone based carrying material/substrate;
to form a solar cell, which basically is flexible and elastic;
to form a solar cell, which basically in its flexible and elastic form may be mounted on a rigid surface or carrier, which reduces or removes this flexibility/elasticity.

Furthermore the solar cell may be a combination of a photovoltaic solar cell layer 3, which is positioned in a front position and a thermo electric transducer layer 3′ positioned in a rear position (FIG. 7). The thermoelectric transducer layer 3′ absorbs thermal energy, which is not absorbed by photovoltaic solar cell layer 3, which is positioned at the front side.

Thermoelectric transducers rely on the Seebeck and Peltier effects to convert heat into electrical power. Transducer performance can be summarized using two specifications, the thermodynamic efficiency (the ratio of power generated to power drawn from a heat source) and the power density (the power generated per unit area of the device). These metrics depend on the materials used in the thermoelectric transducer couple, the temperatures of the hot and cold sides of the transducer, and the load driven by the transducer.

The solar cell may be of a p-i-n type conductive layers of correct formation of amorphous hydrogen based silicon. Amorphous silicon absorbs about 40 times more efficiently than that of crystalline silicon. As TCO layer in the first layer uses indium tin oxide (ITO). In order to increase the effect of the solar cell, an anti-reflective coating (ARC) may be applied. The temperature of the substrate shall be as lowest as possible, which by way of example, is in the range of 100°-400° C. and preferably in the range of 150°-250° C. It is otherwise impossible afterwards to deposit on a flexible polymer substrate.

The individual layers may be deposited by reactive RF-/DC-sputtering in an Ar/H₂ atmosphere. Hydrogen is added in order to fill out the present “dangling bonds” in the amorphous silicon layer, as these otherwise function as electron traps that lower the efficiency.

p-i-n-type layers:

p-Si layer: Thickness abt. 8 nm DC-sputtering rate=3,5-9 nm/min
i-Si layer: Thickness abt. 400-500 nm RF-sputtering rate=7-8 nm/min
n-Si layer: Thickness abt. 20 nm DC-sputtering rate=3-10 nm/min

Depositing of layers:
Usually the metal layers (by way of example the rear side electrode) will be deposited by DC-sputtering.
Usually metal oxides (by way of example the front side electrode, the TCO layer) will be deposited by RF-sputtering. However, CVD and PECVD is also possible.
n-Si and p-Si layers can be deposited by DC-sputtering, but will more likely be deposited by RF-sputtering. However, CVD and PECVD is also possible.
i-Si (the thick Si layer) can be deposited by RF-sputtering, PECVD or CVD.

During the depositing by sputtering, the temperature of the substrate shall possibly be high (˜200° C.). Therefore it is very important to be able to control the temperature of the substrate during the depositing/sputtering.

A production of a transducer according to the form of a solar cell on a substrate in the form of a preferably silicone web or foil, is achieved by carrying the silicone web or foil with the front side facing upwards while supported on a top course of an endless conveyor or a similar transportation unit in successive order through the following treatment stations:
in a first treatment station, providing the surface pattern of the front side of the substrate with a plasma treating in an argon (Ar) atmosphere;
in a second treatment station, applying by RF-/DC-sputtering a rear side electrode an electric conductive layer in an argon (Ar) atmosphere;
in a third treatment station, applying by RF-/DC-sputtering one or more group of layers each of a n-Si layer, a i-Si layer and a p-Si layer to the surface pattern of the front side of the substrate in an atmosphere of argon/hydrogen (Ar/H₂);
in a fourth treatment station, applying by RF-sputtering a front side electrode of an electrically conductive layer in an argon/oxygen (Ar/O₂) atmosphere;
in a possible fifth treatment station, applying an anti-reflective (ARC) layer in an argon (Ar) atmosphere; and
in a final treatment station, at the end of the endless belt conveyor, rolling up the finished solar cell.

A new and improved method for the production of not just flexible but also elastic solar cells is achieved with a possible length from 20 mm to 20000 mm or more and a width from 100 mm to 1500 mm, for example approximately 500 mm. In other words, the new solar cells of the invention may be provided in rolls with a length as required by the customers. Of course the width and the length of the solar cells may be further adapted in accordance with specific customer orders.

The surface pattern of the front side of the silicone substrate causes a very significant increase of the area of the photovoltaic (electricity generating) layer of the solar cell, which means a similar significant increase of the efficiency of the solar cell according to the invention.

A very important further advantage is the economical side of the invention because also the production price and as a consequence also the sales price of the solar cells per area unit may be considerably minimized.

More specifically, the method of the production of a transducer in accordance to the invention carries silicone web or foil with the front side facing upwards while supported on a top course of an endless conveyor or a similar transportation unit in successive order through the following treatment stations:
in a first treatment station, providing the surface pattern of the front side of the substrate with a plasma treating in an argon (Ar) atmosphere;
in a second treatment station, applying by DC-sputtering a rear side electrode in the form of a layer of silver (Ag) in an argon (Ar) atmosphere;
in a third treatment station, applying by RF-/DC-sputtering one or more group of layers each of a n-Si layer, a i-Si layer and a p-Si layer to the surface pattern of the front side of the substrate in an atmosphere of argon/hydrogen (Ar/H₂);
in a fourth treatment station, applying by RF-sputtering a front side electrode either as a layer of indium tin oxide (ITO) or as a layer of zinc oxide (ZnO₂) which, in both cases, is in an argon/oxygen (Ar/O₂) atmosphere;
in a possible fifth treatment station, applying an anti-reflective (ARC) layer in an argon (Ar) atmosphere; and
in a final treatment station, at the end of the endless belt conveyor, rolling up the finished solar cell.

In another embodiment of the invention, the transducer is a light emitting device.

In this embodiment a voltage is applied to the electrically conductive terminals on the rear side and the front side, which will reverse the function of the transducer to emit photons of light.

Given the three-dimensional surface pattern of raised and depressed surface portions that is formed, the surface serves as a light emitter from which the photons will escape the “light-trap” in an opposite direction compared to the capture of light when the transducer is working as a solar cell.

Having a randomly formed surface, the light will escape in a diffuse way suitable for creating a subtle lighting element ideal for providing say a luminescent layer. If given an orderly formed surface, the light will escape in an orderly predetermined manner.

Finally, it should furthermore be mentioned that a transducer according to the invention in the form of a solar cell mounted on a specific surface could be combined with a transducer according to the invention in the form of a light emitting device, where the latter could possible form a light advertising sign fitted as part of, by way example, the front surface of a building which is mounted with a transducer in the form of a solar cell according to the invention.

### TECHNICAL TERMS

PV: Photovoltaic
RF: Radio Frequency
DC: Direct Current
ARC: Anti-Reflective Coating
TCO: Transparent Conductive Oxide
PVD: Physical Vapour Deposition
CVD: Chemical Vapour Deposition
PECVD: Plasma Enhanced Chemical Vapour Deposition

### DRAWING REFERENCE NUMBERS

1: Substrate (silicone foil or web, carrying material)
2: Rear side electrode (connector)
3: Photoelectric active (photovoltaic) layer (electricity generating layer)
4: Front side electrode (connector)
5: Substrate (silicone foil or web)
7: Solar light (incoming solar light)
8: Vision through the solar cell (front side and rear side electrodes are transparent)
9: Transducer (solar cell)
10: Upper protective layer (possibly transparent)
A: Rear side electrode (terminal/connector)
B: Front side electrode (terminal/connector)
C: Front side electrode (terminal/connector)
D: Rear side electrode (terminal/connector)

1-9. (canceled)

10. A photoelectric transducer comprising:
a substrate;
a rear side electrode;
a photoelectric active layer; and
a front side electrode; and wherein
the substrate is a flexible, elastic silicone web or foil, with a front side of the substrate including a three-dimensional surface pattern of raised and depressed surface portions formed therein, the photoelectric active layer being deposited onto the three-dimensional surface pattern so that the front side electrode and the rear side electrode include electrically conductive layers, which comprise electrically conductive materials, or which is provided with electrically conductive coatings, comprising a front protection layer which is a transparent, elastic silicone web or foil.

11. A transducer according to claim 10, wherein the substrate comprises a polyurethane web or foil.

12. A transducer according to claim 10, wherein the photoelectric active layer comprises a photoelectric active coating of a silicon compound comprising amorphous or crystalline silicon.

13. A transducer according to claim 10, wherein the surface pattern comprises waves including troughs and crests extending in one common direction and each wave has a height which is a shortest distance between a crest and neighboring troughs.

14. A transducer according to claim 10, wherein the surface pattern comprises waves including troughs and crests with the troughs and crests defining wave fronts extending in at least two directions along the surface of the substrate.

15. A transducer according to claim 10, wherein the surface pattern defines a plurality of funnels with each funnel defining interior wall parts arranged relative to each other so that light incident on an interior wall part of a funnel is reflected onto another interior wall part of the funnel.

16. A transducer according to claim 10, wherein the transducer is a solar cell comprising a photovoltaic part and a thermoelectric part disposed adjacent to each other.

17. A transducer according to claim 10, wherein the photovoltaic part is disposed in a front position and the thermoelectric part is disposed in a rear position.

18. A transducer according to claim 10, wherein the transducer is a light emitting device.
